(19) United States
(12) Patent Application Publication
(10) Pub. No.: US 2022/0123252 A1
(43) Pub. Date: Apr. 21, 2022

(54) DISPLAY SUBSTRATE AND MANUFACTURING METHOD THEREOF, DISPLAY PANEL AND DISPLAY DEVICE

(71) Applicants: Chengdu BOE Optoelectronics Technology Co., Ltd., Chengdu (CN); BOE Technology Group Co., Ltd., Beijing (CN)

(72) Inventor: Yige QI, Beijing (CN)

(21) Appl. No.: 17/359,491

(22) Filed: Jun. 25, 2021

(30) Foreign Application Priority Data
Oct. 20, 2020 (CN) 202011126836.8

(51) Int. Cl. H01L 51/50; H01L 51/56; H01L 27/32; H01L 51/52

(52) U.S. Cl. CPC H01L 51/5088; H01L 51/56; H01L 27/3246; H01L 51/5293; H01L 51/5072; H01L 51/5237; H01L 51/5056

(57) ABSTRACT

A method of manufacturing a display substrate, includes: providing a substrate; forming an anode layer on the substrate and a hole injection layer on the anode layer, the anode layer comprising a plurality of anode blocks arranged at intervals, and the hole injection layer comprising a plurality of hole injection portions arranged at intervals, the plurality of hole injection portions disposed on the plurality of anode blocks in a one-to-one correspondence; forming a pixel definition layer on the hole injection layer, the pixel definition layer provided with a plurality of pixel openings, which expose the plurality of hole injection portions in a one-to-one correspondence; forming an organic light-emitting material layer which is located at least partially in each of the plurality of pixel openings; and forming a cathode layer, which covers a side of the organic light-emitting material away from the substrate.

### CROSS REFERENCE TO RELATED APPLICATIONS

This disclosure claims the priority of a Chinese patent application filed with National Intellectual Property Administration, P. R. C., under CN 202011126836.8, entitled “Display Substrate And Manufacturing Method Thereof, Display Panel And Display Device” on Oct. 20, 2020, the entire contents of which are incorporated by reference in this disclosure.

### TECHNICAL FIELD

Embodiments of the present disclosure relate to a display substrate, a manufacturing method thereof, a display panel, and a display device.

### BACKGROUND

OLED (Organic Light-Emitting Diode) has the advantages of wide viewing angle, fast response, high contrast, etc., and has been broadly applied in various display devices.

In the OLED display devices known to the inventors, crosstalk occurs to adjacent sub-pixels of different colors during display. For example, in a case that a red sub-pixel is lit on, adjacent green sub-pixel or blue sub-pixel may be abnormally lit on, resulting in color cast in displayed images, which is particularly significant at low gray levels, and affecting the user experience.

### SUMMARY

At least one embodiment of the present disclosure provides a method of manufacturing a display substrate, including: providing a substrate; forming an anode layer on the substrate and a hole injection layer on the anode layer, the anode layer comprising a plurality of anode blocks arranged at intervals, and the hole injection layer comprising a plurality of hole injection portions arranged at intervals, the plurality of hole injection portions disposed on the plurality of anode blocks in a one-to-one correspondence; forming a pixel definition layer on the hole injection layer, the pixel definition layer provided with a plurality of pixel openings, which expose the plurality of hole injection portions in a one-to-one correspondence; forming an organic light-emitting material layer which is located at least partially in each of the plurality of pixel openings; and forming a cathode layer, which covers a side of the organic light-emitting material away from the substrate.

In an embodiment of the present disclosure, material for the hole injection portion is a metal oxide; forming the anode layer on the substrate and the hole injection layer on the anode layer includes: forming an anode material film on the substrate and a metal oxide film on the anode material film; and etching the anode material film and the metal oxide film simultaneously to obtain the plurality of anode blocks and the plurality of hole injection portions.

In an embodiment of the present disclosure, etching the anode material film and the metal oxide film simultaneously includes: etching the anode material film and the metal oxide film simultaneously with an etchant which comprises a nitric acid and a phosphoric acid.

In an embodiment of the present disclosure, forming the anode material film on the substrate and the metal oxide film on the anode material film includes: forming the anode material film and the metal oxide film on the substrate sequentially through a magnetron sputtering process.

In an embodiment of the present disclosure, material for the hole injection portion includes at least one of niobium pentoxide, nickel oxide, titanium oxide, and molybdenum oxide.

In an embodiment of the present disclosure, a thickness of the hole injection portion ranges from 10 Å to 30 Å.

At least one embodiment of the present disclosure provides a display substrate, including:

a substrate;

an anode layer, which is disposed on the substrate and includes a plurality of anode blocks arranged at intervals;

a hole injection layer, which is disposed on the anode layer and includes a plurality of hole injection portions arranged at intervals, the plurality of hole injection portions disposed on the plurality of anodes in a one-to-one correspondence;

a pixel definition layer, which is provided with a plurality of pixel openings, which expose the plurality of hole injection portions in a one-to-one correspondence;

an organic light-emitting material layer, disposed at least partially in each of the plurality of pixel openings; and

a cathode layer, disposed on the organic light-emitting layer and covering a side of the organic light-emitting material layer away from the substrate.

In an embodiment of the present disclosure, material for the hole injection portion includes a metal oxide.

In an embodiment of the present disclosure, material for the hole injection portion includes at least one of niobium pentoxide, nickel oxide, titanium oxide, and molybdenum oxide.

In an embodiment of the present disclosure, a thickness of the hole injection portion ranges from 10 Å to 30 Å.

In an embodiment of the present disclosure, the display substrate further includes a driving circuit layer disposed between the substrate and the anode layer.

In an embodiment of the present disclosure, the display substrate further includes a barrier layer and a buffer layer, wherein the barrier layer is disposed between the substrate and the buffer layer, the buffer layer is disposed between the barrier layer and the driving circuit layer.

In an embodiment of the present disclosure, the display substrate further includes a hole transport layer and an electron transport layer, wherein the hole transport layer is disposed between the hole injection layer and the organic light-emitting material layer, and the electron transport layer is disposed between the organic light-emitting material layer and the cathode layer.

In an embodiment of the present disclosure, both the hole transport layer and the electron transport layer are a common layer.

In an embodiment of the present disclosure, the display substrate further includes a light coupling layer and an encapsulation layer, wherein the light coupling layer is disposed on the cathode layer, and the encapsulation layer is disposed on the light coupling layer.

In an embodiment of the present disclosure, the encapsulation layer is a thin film encapsulation layer.

At least one embodiment of the present disclosure further provides a display panel including the display substrate as described above.

In an embodiment of the present disclosure, the display panel further includes a polarizer covering a side of the display substrate facing away from the substrate.

At least one embodiment of the present disclosure further provides a display device comprising the display panel as described above.

### BRIEF DESCRIPTION OF THE DRAWINGS

FIG. 1 illustrates a flowchart of a method of manufacturing a display substrate according to an embodiment of the present disclosure;

FIG. 2 illustrates a partial cross-sectional view of a first intermediate structure of a display substrate according to an embodiment of the present disclosure;

FIG. 3 illustrates a partial cross-sectional view of a second intermediate structure of a display substrate according to an embodiment of the present disclosure;

FIG. 4 illustrates a partial cross-sectional view of a third intermediate structure of a display substrate according to an embodiment of the present disclosure;

FIG. 5 illustrates a top view of a third intermediate structure of a display substrate according to an embodiment of the present disclosure;

FIG. 6 illustrates a partial cross-sectional view of a fourth intermediate structure of a display substrate according to an embodiment of the present disclosure;

FIG. 7 illustrates a partial cross-sectional view of a fifth intermediate structure of a display substrate according to an embodiment of the present disclosure;

FIG. 8 illustrates a schematic partial cross-sectional view of a display substrate according to an embodiment of the present disclosure;

FIG. 9 illustrates a comparison of relationship between a green light x-axis color coordinate and a brightness of a display substrate according to an embodiment of the present disclosure and of a display substrate known to the inventors; and

FIG. 10 illustrates a comparison of relationship between a white light x-axis color coordinate and a brightness of a display substrate according to an embodiment of the present disclosure and of a display substrate known to the inventors.

### DETAILED DESCRIPTION OF THE EMBODIMENTS

Exemplary embodiments will be described in detail here, and examples thereof are illustrated in the accompanying drawings. In a case that the following description refers to the drawings, unless otherwise indicated, the same reference signs in different drawings designate the same or similar elements. The implementations described in the following exemplary embodiments do not represent all implementations consistent with the present disclosure. Rather, they are merely examples of devices and methods consistent with some aspects of the present disclosure as detailed in the appended claims.

The terms used in the present disclosure are only for the purpose of describing specific embodiments, and are not intended to limit the present disclosure. The singular forms of “a”, “said” and “the” used in the present disclosure and appended claims are also intended to include plural forms, unless the context clearly indicates other meanings. It should also be understood that the term “and/or” as used herein refers to and includes any or all possible combinations of one or more associated items that are listed.

It should be understood that although the terms first, second, third, etc. may be used in this disclosure to describe various information, the information should not be limited to these terms. These terms are only used to distinguish the same type of information from each other. For example, without departing from the scope of the present disclosure, the first information may also be referred to as second information, and similarly, the second information may also be referred to as first information. Depending on the context, the word “if” as used herein may be interpreted as “when” or “upon” or “in response to determining”.

In the display panel known to the inventors, crosstalk occurs between adjacent sub-pixels of different colors during display, resulting in color cast. The inventors found that the reason for the color cast is that a hole injection layer disposed above an anode is a common layer, and the hole injection layer is typically doped with P-type dopants, which has a relatively high hole mobility; and in a case that the pixel density of the display panel is relatively high, a spacing between adjacent sub-pixels is relatively small. For the above two reasons, holes may be transferred to adjacent sub-pixels of other colors through the hole injection layer in a case that the sub-pixels are lit on, causing the adjacent sub-pixels of different colors to be abnormally lit on (slightly bright), that is, color cast may occur to the display panel, which affects the user experience.

Embodiments of the present disclosure provide a display substrate, a manufacturing method thereof, a display panel, and a display device. In the following, in conjunction with the accompanying drawings, the display substrate and the manufacturing method thereof, the display panel, and the display device according to the embodiments of the present disclosure will be described in detail. In the case of no conflict, the features in the following embodiments can be mutually supplemented to or combined with each other.

At least one embodiment of the present disclosure provides a method of manufacturing a display substrate. The process of manufacturing the display substrate is introduced below. The term “patterning process” in the present disclosure includes processes such as depositing a film layer, coating photoresist, mask exposure, developing, etching, and stripping photoresist, and etc. The deposition can be any one or more selected from sputtering, evaporation and chemical vapor deposition, and the etching can be any one or more selected from dry etching and wet etching. “Film” refers to a film layer made by depositing or coating a certain material on a substrate. In a case that the “film” does not require a patterning process during the entire production process, the “film” can also be referred to as a “layer”. In a case that the “film” is to be patterned during the whole manufacturing process, it is called a “film” before the patterning process, and it can be called a “layer” after the patterning process. The “layer” after the patterning process contains at least one “pattern”.

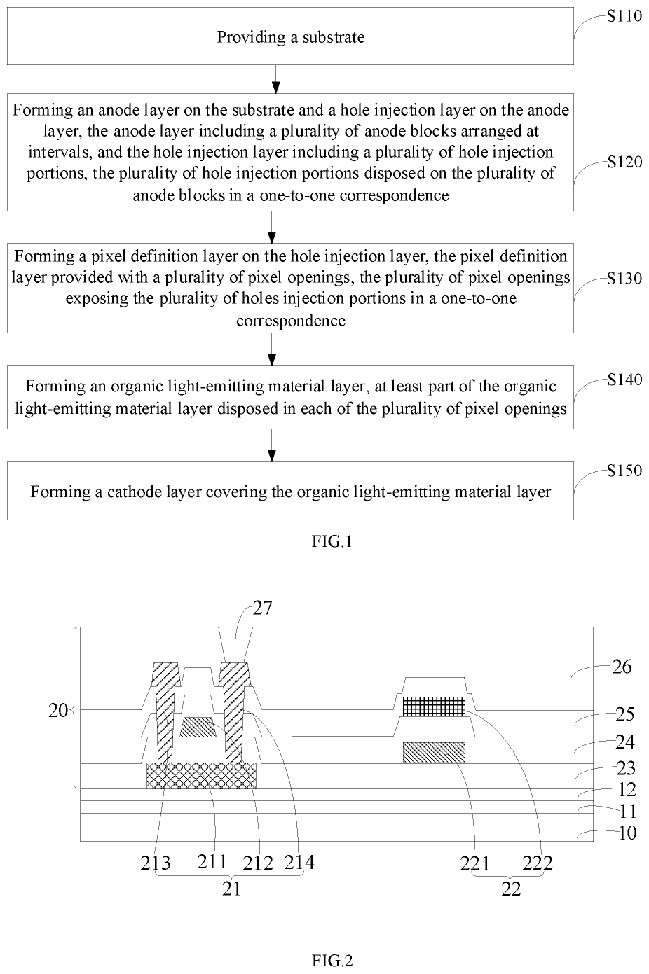

Referring to FIG. 1, the method for preparing a display substrate includes:

In step S110, a substrate is provided;

In step S120, an anode layer on the substrate and a hole injection layer on the anode layer are formed, the anode layer including a plurality of anode blocks arranged at intervals, and the hole injection layer including a plurality of hole injection portions, the plurality of hole injection portions disposed on the plurality of anode blocks in a one-to-one correspondence;

In step S130, a pixel definition layer is formed on the hole injection layer, the pixel definition layer is provided with a plurality of pixel openings, and the plurality of pixel openings expose the plurality of holes injection portions in a one-to-one correspondence.

In step S140, an organic light-emitting material layer is formed, and at least part of the organic light-emitting material layer is disposed in each of the plurality of pixel openings; and

In step S150, a cathode layer covering the organic light-emitting material layer is formed.

In an embodiment of the present disclosure, the substrate is a flexible substrate, and material for the flexible substrate may be selected from a group comprising PET (Polyethylene terephthalate), PI (polyimide) and PC (polycarbonate). In some embodiments of the present disclosure, the substrate is a rigid substrate, and material for the rigid substrate may be glass, metal, or the like.

In an embodiment of the present disclosure, after step S110 and before step S120, the method further includes: sequentially forming a barrier layer and a buffer layer on the substrate.

In an embodiment of the present disclosure, before step S120, the method further includes: forming a driving circuit layer on the substrate. The driving circuit layer may be formed on a side of the buffer layer away from the substrate.

After forming the driving circuit layer, a first intermediate structure as illustrated in FIG. 2 can be obtained.

Referring to FIG. 2, the driving circuit layer 20 is disposed on the buffer layer 12, and the barrier layer 11 is disposed between the substrate 10 and the buffer layer 12. The driving circuit layer 20 includes a pixel driving circuit. The pixel driving circuit is configured to drive the sub-pixels of the display substrate to emit light, and the pixel driving circuit includes a thin film transistor 21 and a capacitor 22. The thin film transistor 21 includes an active layer 211, a gate electrode 212, a source electrode 213, and a drain electrode 214. The capacitor 22 includes a first electrode plate 221 and a second electrode plate 222. The driving circuit layer 20 further includes a gate insulating layer 23, a capacitor insulating layer 24, an interlayer dielectric layer 25, and a planarization layer 26.

In an embodiment of the present disclosure, forming the driving circuit layer on the substrate may include:

First, an active material film is deposited on the substrate 10, and the active material film is patterned through a patterning process to form an active layer 211.

Subsequently, the gate insulating layer 23 and the first metal film are sequentially deposited, and the first metal film is patterned through a patterning process to form a gate electrode 212 and a first electrode plate 221.

Subsequently, a capacitor insulating layer 24 and a second metal film are sequentially deposited, and the second metal film is patterned through a patterning process to form a second electrode plate 222. An orthographic projection of the second electrode plate 222 on the substrate 10 at least partially overlaps an orthographic projection of the first electrode plate 221 on the substrate 10.

Subsequently, an interlayer dielectric layer 25 is deposited, and the gate insulating layer 23, the capacitor insulating layer 24, and the interlayer dielectric layer 25 are etched to form a via hole passing through the gate insulating layer 23, the capacitor insulating layer 24, and the interlayer dielectric layer 25. And a plurality of via holes are formed over the active layer 211 correspondingly.

Subsequently, a third metal film is deposited, and the third metal film is patterned through a patterning process to form a source electrode 213 and a drain electrode 214. The source electrode 213 and the drain electrode 214 are electrically connected to the active layer 211 through a corresponding via hole, respectively. The third metal film may include two titanium films and an aluminum film sandwiched between the two titanium films.

Subsequently, a planarization layer 26 is formed. The planarization layer 26 covers the source electrode 213, the drain electrode 214, and exposed interlayer dielectric layer 25. A surface of the planarization layer 26 that faces away from the substrate 10 is a planar surface, so that other film layers are subsequently formed on a side of the planarization layer 26 that faces away from the substrate 10.

Subsequently, the planarization layer 26 is etched to form a via hole 27 passing through the planarization layer 26, and the via hole 27 exposes at least part of a surface of the drain electrode 214 away from the substrate 10.

In an embodiment of the present disclosure, in step S120, material for the hole injection portion comprises a metal oxide. Forming the anode layer and the hole injection layer on the anode layer on the substrate includes:

Forming an anode material film on the substrate and a metal oxide film on the anode material film, and both orthographic projections of the anode material film and the metal oxide film on the substrate cover the substrate; and

The anode material film and the metal oxide film are simultaneously etched to obtain a plurality of anode blocks and a plurality of hole injection portions disposed on respective anode blocks.

Material for the hole injection portion includes a metal oxide, and material for the anode layer typically includes a metal or a metal oxide. The anode material film and the metal oxide film can be etched through a single etching process, which helps to simplify the manufacturing process. Etching the anode material film layer and the metal oxide film layer at the same time only requires a mask, without increasing the number of the masks, and there is no other spacing structure between the hole injection portions, structural complexity of the display panel will not be increased.

In some embodiments of the present disclosure, material for the hole injection portion includes at least one of niobium pentoxide, nickel oxide, titanium oxide, and molybdenum oxide. In this way, a stable dipole layer may be formed at an interface between the hole injection portion and a hole transport layer disposed on a side of the hole injection portion away from the substrate, which is more helpful to reduce the barrier of hole injection and increase hole injection capability. Compared with the solution of reducing the signal crosstalk between sub-pixels of different colors by reducing the P-type dopant concentration, a driving voltage for the display substrate in the embodiments of the present disclosure is smaller, which helps to reduce power consumption.

In some embodiments of the present disclosure, the anode block has a laminated structure, which may include two transparent metal oxide films and a metal film sandwiched between the two transparent metal oxide films. Material for the transparent metal oxide film may be indium tin oxide, and material for the metal film may be metallic silver. A thickness of the transparent metal oxide film is, for example, 70 Å, and a thickness of the metal film is, for example, 1000 Å.

In an embodiment of the present disclosure, forming the anode material film on the substrate and the metal oxide film on the anode material film includes: forming the anode material film and the metal oxide film sequentially on the substrate through a magnetron sputtering.

In this way, the manufacturing of the anode material film and the metal oxide film can be completed through a single magnetron sputtering apparatus, and it is only required to replace a target material. The operation is relatively simple, which helps to simplify the manufacturing process.

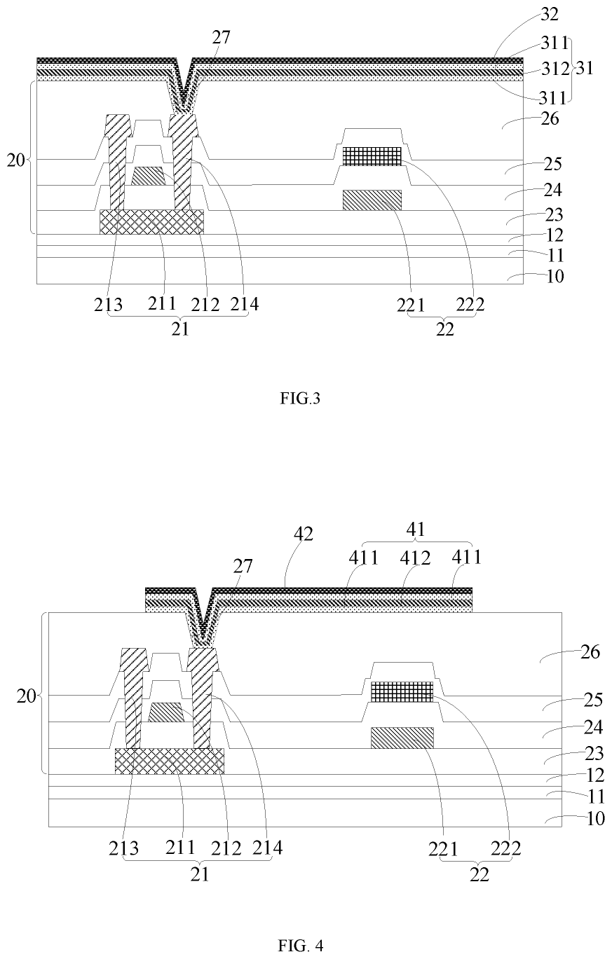

Through the above process, a second intermediate structure as illustrated in FIG. 3 can be obtained. Referring to FIG. 3, an anode material film 31 is formed on a side of the driving circuit layer 20 away from the substrate 10. The anode material film 31 includes two transparent metal oxide films 311 and a metal film 312 sandwiched between the two transparent metal oxide films 311. The metal oxide film 32 is disposed on a side of the anode material film 31 away from the substrate 10. The anode material film 31 is electrically connected to the drain electrode 214 through the via hole 27.

In some embodiments of the present disclosure, the anode block includes two indium tin oxide films and a silver film sandwiched between the two indium tin oxide films. Material for the hole injection portion is niobium pentoxide, and the magnetron sputtering apparatus needs to use indium tin oxide target, silver target and niobium pentoxide target. During the magnetron sputtering, the indium tin oxide target material is first bombarded to form an indium tin oxide film on a side of the planarization layer away from the substrate, and then the silver target material is bombarded to form a silver film on a side of the indium tin oxide film away from the substrate, and then, the indium tin oxide target material is bombarded again to form an indium tin oxide film on a side of the silver film away from the substrate, and finally the niobium pentoxide target material is bombarded to form a niobium pentoxide film on a side of the indium tin oxide film away from the substrate.

In an embodiment of the present disclosure, etching the anode material film and the metal oxide film simultaneously includes: etching the anode material film and the metal oxide film through an etchant simultaneously, the etchant includes nitric acid and phosphoric acid.

Compared with a dry etching process, etching the anode material film and the metal oxide film through the etchant left less residues. The nitric acid and the phosphoric acid have strong oxidizing properties, which are helpful to etch the anode material film and the metal oxide film. In some embodiments of the present disclosure, the etchant may be obtained by mixing 5% by mass nitric acid, 60% by mass phosphoric acid, and other additives.

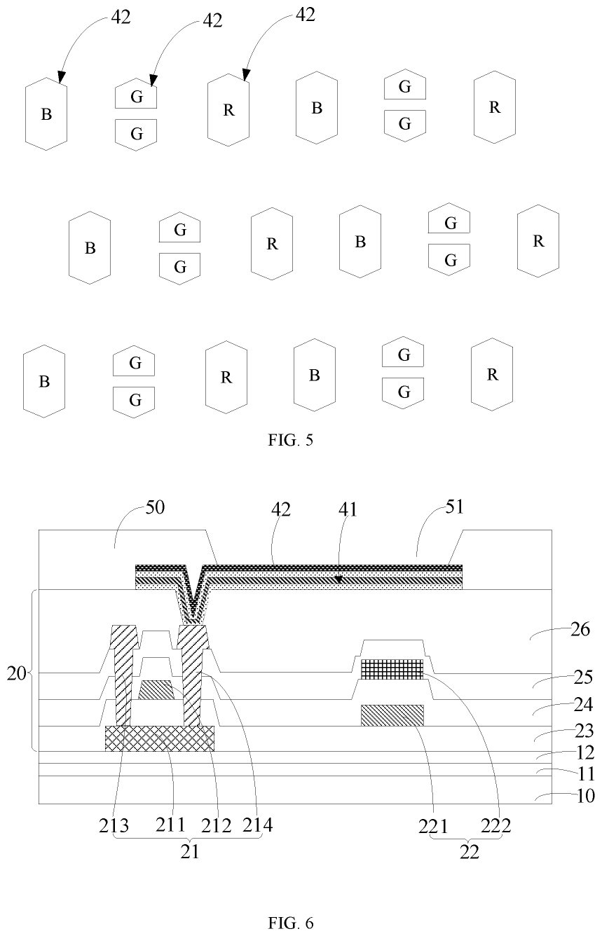

Through this operation, a third intermediate structure as illustrated in FIGS. 4 and 5 can be obtained. Referring to FIG. 4, the anode block 41 includes two transparent metal oxide films 411 and a metal film 412 sandwiched between the two transparent metal oxide films 411. Since the anode material film and the metal oxide film are etched at the same time, an orthographic projection of the anode block 41 on the substrate 10 and an orthographic projection of the hole injection portion 42 on the substrate 10 substantially coincide. Each anode block 41 is electrically connected to the drain electrode 214 of a corresponding thin film transistor 21 through the via hole 27. Referring to FIG. 5, a plurality of hole injection portions 42 are arranged at intervals. The display panel may include three sub-pixels, namely, a red sub-pixel, a green sub-pixel and a blue sub-pixel, wherein a hole injection portion 42 marked with R indicates a hole injection portion corresponding to the red sub-pixel, the hole injection portion 42 marked with G indicates a hole injection portion corresponding to the green sub-pixel, and the hole injection portion 42 marked B indicates a hole injection portion corresponding to the blue sub-pixel. FIG. 5 only illustrates an arrangement of the hole injection portions 42 corresponding to one pixel arrangement. In other embodiments of the present disclosure, the hole injection portions 42 may be arranged in other ways.

In an embodiment of the present disclosure, a thickness of the hole injection portion 42 ranges from 10 Å to 30 Å. Such a configuration can prevent the hole injection portion 42 from being too thin in thickness, resulting in poor film formation of the hole injection portion and breakage at certain locations, which affects the performance of the display panel; and it can also prevent the hole injection portion 42 from being too thick, which results in increase in the thickness of the display panel and increase in cost. The thickness of the hole injection portion 42 is, for example, 10 Å, 15 Å, 20 Å, 25 Å, 30 Å, or the like.

After forming the anode layer on the substrate and the hole injection layer on the anode layer, in step S130, a pixel definition layer 50 is formed on the hole injection layer, and the pixel definition layer 50 is provided with a plurality of pixel openings 51, and the plurality of pixel openings 51 expose the plurality of hole injection portions 42 in a one-to-one correspondence.

A fourth intermediate structure as illustrated in FIG. 6 can be obtained through step S130. Referring to FIG. 6, the pixel definition layer 50 covers an edge area of the hole injection portion 42, and a central area of the hole injection portion 42 is exposed by the pixel opening 51.

In the embodiment of the present disclosure, the hole injection portion 42 is formed before the pixel definition layer 50. If the pixel definition layer is formed before the hole injection portion, a magnetron sputtering process for forming the hole injection portion may affect the appearance of the pixel definition layer 50 and a slope angle of the pixel opening 51, which in turn affects light output of the display panel.

After the pixel definition layer is formed, the organic light emitting material layer is formed at least partially in the pixel opening (step S140).

In an embodiment of the present disclosure, before step 140, the method further includes: forming a hole transport layer 43, and an orthographic projection of the hole transport layer 43 on the substrate 10 covers the substrate 10.

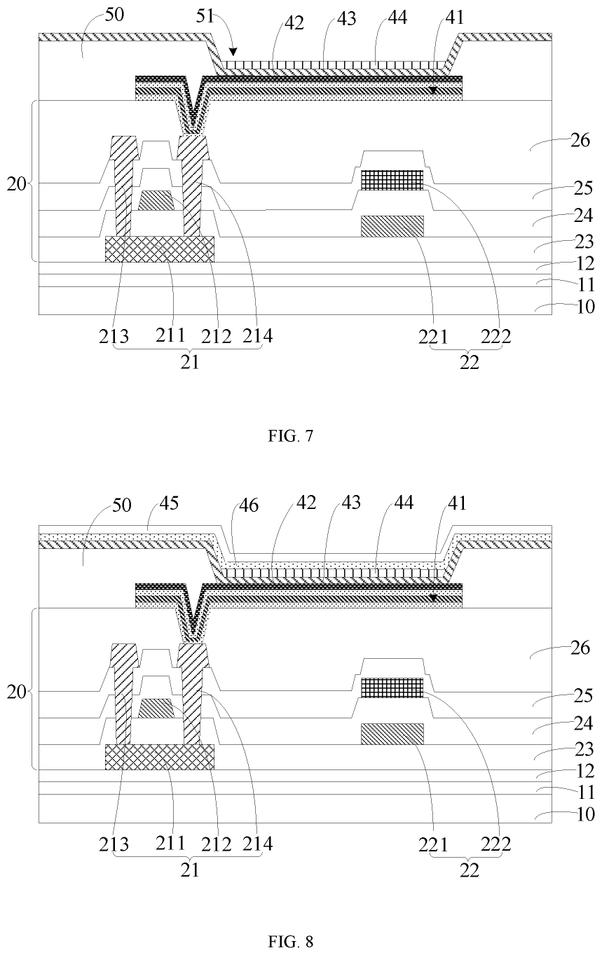

A fifth intermediate structure as illustrated in FIG. 7 can be obtained through step S140. Referring to FIG. 7, the hole transport layer 43 is a common layer, the organic light-emitting material layer 44 is disposed on a side of the hole transport layer 43 away from the substrate 10, and the organic light-emitting material layer 44 is at least partially located in each of the plurality of pixel openings.

After forming the organic light-emitting material layer, a cathode layer covering the organic light-emitting material layer is formed (step S150).

In an embodiment of the present disclosure, before step S150, the method further includes: forming an electron transport layer on a side of the organic light-emitting material layer away from the substrate, and the cathode layer is formed on a side of the electron transport layer away from the substrate.

A display substrate as illustrated in FIG. 8 can be obtained through step S150. Referring to FIG. 8, the cathode layer 45 is a plane electrode on the entire surface. The electron transport layer 46 is a common layer, and an orthographic projection on the substrate 10 covers the substrate 10.

In some embodiments of the present disclosure, before step S150, the method further includes: forming an electron injection layer on a side of the electron transport layer away from the substrate, wherein the electron injection layer may be a common layer.

In some embodiments of the present disclosure, after step S150, the method may further include: forming a light coupling layer and an encapsulation layer on a side of the cathode layer 45 away from the substrate. The encapsulation layer may be a thin film encapsulation layer.

In the method of preparing a display substrate according to an embodiment of the present disclosure, the formed hole injection layer includes a hole injection portion disposed on respective anode blocks, and adjacent hole injection portions are separated from each other such that hole transmission between adjacent hole injection portions is avoided and signal crosstalk between different sub-pixels may be eliminated, and adjacent sub-pixels of other colors is prevented from being abnormally lighted in a case that a sub-pixel is lit, thereby reducing the color cast of the display panel.

At least one embodiment of the present disclosure further provides a display substrate. Referring to FIG. 8, the display substrate includes a substrate 10, an anode layer disposed on the substrate, a hole injection layer disposed on the anode layer, and a pixel definition layer disposed on the substrate 10 and covering an edge area of the hole injection layer, an organic light-emitting material layer 44 and a cathode layer 45. The anode layer includes a plurality of anode blocks 41 arranged at intervals. The hole injection layer includes a plurality of hole injection portions 42 arranged at intervals, and the plurality of hole injection portions are disposed on the plurality of anode blocks in a one-to-one correspondence. The pixel definition layer 50 is provided with a plurality of pixel openings, and the plurality of pixel openings expose the plurality of hole injection portions 42 in a one-to-one correspondence. The organic light-emitting material layer 44 is located at least partially in each of the plurality of pixel openings. The cathode layer 45 is disposed on the organic light-emitting layer and covers a side of the organic light-emitting material layer 44 away from the substrate 10.

In an embodiment of the present disclosure, an orthographic projection of the cathode layer 45 on the substrate 10 covers an entire surface of the substrate 10.

In the display substrate according to the embodiment of the present disclosure, the hole injection layer includes a hole injection portion located on respective anode blocks, and adjacent hole injection portions are arranged at intervals to avoid hole transmission between adjacent hole injection portions. Thus, signal crosstalk between different sub-pixels are eliminated, and adjacent sub-pixels of other colors is prevented from being abnormally lit on in a case that a sub-pixel is lit on, thereby reducing the color cast of the display panel.

In an embodiment of the present disclosure, material for the hole injection portion 42 comprises metal oxide.

In an embodiment of the present disclosure, material for the hole injection portion 42 includes at least one of niobium pentoxide, nickel oxide, titanium oxide, and molybdenum oxide.

In an embodiment of the present disclosure, a thickness of the hole injection portion 42 ranges from 10 Å to 30 Å.

In an embodiment of the present disclosure, the display substrate further includes a driving circuit layer 20 disposed between the substrate 10 and the anode layer. The driving circuit layer 20 includes a plurality of pixel driving circuits. The pixel driving circuit is configured to drive the sub-pixels of the display substrate to emit light, and the pixel driving circuit includes a thin film transistor 21 and a capacitor 22. The thin film transistor 21 includes an active layer 211, a gate electrode 212, a source electrode 213, and a drain electrode 214. The capacitor 22 includes a first electrode plate 221 and a second electrode plate 222. The driving circuit layer 20 further includes a gate insulating layer 23 disposed between the active layer 211 and the gate electrode 212, a capacitor insulating layer 24 disposed between the gate electrode 212 and the second electrode plate 222, and an interlayer dielectric layer 25 disposed between the second electrode plate 222 and a top of the electrodes 213, and a planarization layer 26 disposed on the source electrode 213.

In an embodiment of the present disclosure, the display substrate may further include a barrier layer 11 and a buffer layer 12 disposed between the substrate 10 and the driving circuit layer 20, and the barrier layer 11 is disposed between the substrate 10 and the buffer layer 12.

In an embodiment of the present disclosure, the display substrate may further include a hole transport layer 43 disposed between the hole injection portion 42 and the organic light emitting material layer 44, and an electron transport layer 46 disposed between the organic light emitting material layer 44 and the cathode layer 45, both the hole transport layer 43 and the electron transport layer 46 can be a common layer.

In an embodiment of the present disclosure, the display substrate further includes a light coupling layer and an encapsulation layer disposed on a side of the cathode layer 45 away from the substrate 10. The light coupling layer is disposed on the cathode layer, and the encapsulation layer is disposed on the light coupling layer. The encapsulation layer may be a thin film encapsulation layer.

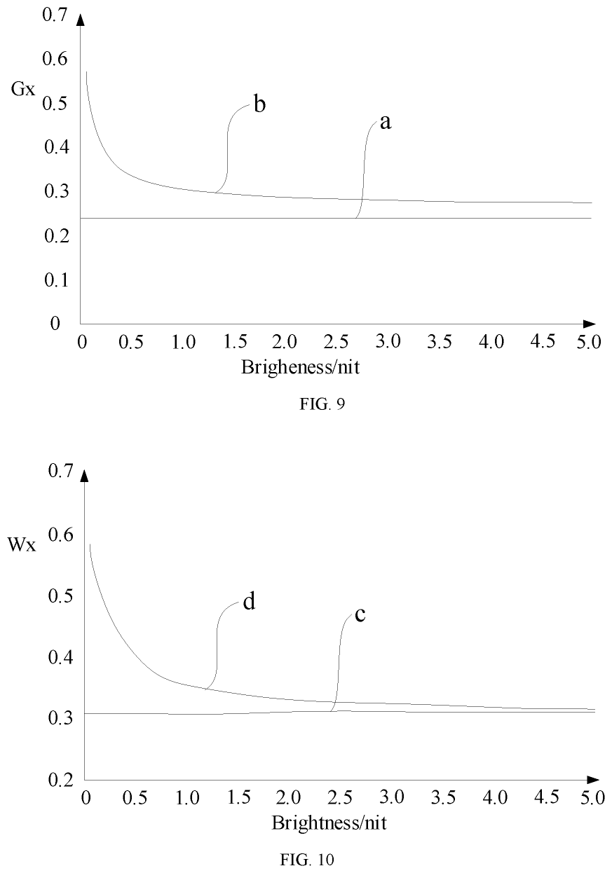

Optical tests are performed on the display substrate according to the embodiment of the present disclosure and the display substrate known to the inventors (in which the hole injection layer is a common layer), and results are illustrated in FIG. 9 and FIG. 10.

FIG. 9 illustrates a comparison of a relationship curve between the green light x-axis color coordinate and a brightness of the two display panels obtained by the test, and the abscissa indicates the brightness, and the ordinate indicates the green light x-axis color coordinate (Gx). In FIG. 9, a curve a indicates a relationship between a green light x-axis color coordinate and a brightness of the display substrate according to the embodiment of the present disclosure, and a curve b indicates a relationship between the green x-axis color coordinate and a brightness of the display substrate known to the inventors. It can be seen from FIG. 9 that the value of the green x-axis color coordinate increases significantly at low gray scales (brightness less than 1 nit) in the display substrate known to the inventors, while the value of the green x-axis color coordinate is kept unchanged substantially at low gray scales in the display substrate according to the embodiment of the present disclosure, which indicates that color cast at low gray scales due to signal crosstalk of pixels of different colors may be avoided in the display substrate according to the embodiments of the present disclosure.

FIG. 10 illustrates a comparison of a relationship between a white light x-axis color coordinate and a brightness of the two display panels obtained by the test, and the abscissa indicates the brightness, and the ordinate indicates the white light x-axis color coordinate (Wx). In FIG. 10, a curve c indicates a relationship between a white light x-axis color coordinate and a brightness of the display substrate according to the embodiment of the present disclosure, and a curve d indicates a relationship between a white light x-axis color coordinate and a brightness of the display substrate know to the inventors. It can be seen from FIG. 10 that the white light x-axis color coordinate of the display substrate known to the inventors increases significantly at low gray scale (brightness less than 1 nit), while the white light x-axis color coordinate of the display substrate according to the embodiment of the present disclosure is kept unchanged substantially at low gray scale, which indicates that color cast at low gray scales due to signal crosstalk of pixels of different colors may be avoided in the display substrate according to the embodiments of the present disclosure.

At least one embodiment of the present disclosure also provides a display panel. The display panel includes any of the above-mentioned display substrates. The display panel may further include a polarizer covering a side of the display substrate away from the substrate.

At least one embodiment of the present disclosure further provides a display device, which includes any one of the display panels as described in the foregoing embodiments.

The display device may further include a housing, and the display panel is mounted in the housing.

The display device according to the embodiments of the present disclosure may be, for example, any device with a display function, such as a mobile phone, a tablet computer, a television, a notebook computer, and a on-board display device. A size of the display panel of the display device may be a micro size (under 1 inch), a medium and small size (from 1 inch to 10 inches), a large size (over 10 inches), and the like. A resolution of the display panel may be 960×540, 1280×720, 2560×1440, 3840×2160, 7680×4320, etc., for example.

As for the method embodiments, since they basically correspond to the product embodiments, for the description of related details and beneficial effects, please refer to the description of the product embodiment, and will not be elaborated here.

It should be noted that in the drawings, the sizes of layers and regions may be exaggerated for clarity of illustration. It should further be understood that in a case that an element or layer is referred to as being “on” another element or layer, it can be directly on the other element or layer or at least one intervening layer may be present. In addition, it should be understood that in a case that an element or layer is referred to as being “under” another element or layer, it can be directly under the other element or layer, or there may be at least one intervening layer or element. In addition, it should further be understood that in a case that a layer or element is referred to as being “between” two layers or two elements, it may be the only layer between the two layers or two elements, or more than one intervening layer or element may also be present. Similar reference signs designate similar elements throughout the specification.

One of ordinary skill in the art will easily conceive of other embodiments of the present disclosure after considering the specification and practicing the disclosure disclosed herein. The present disclosure is intended to cover any variations, applications, or modifications of the present disclosure. These variations, applications, or modifications follow the general principles of the present disclosure and include common knowledge or conventional technical means in the art that are not disclosed in the present disclosure. . The description and the embodiments are to be regarded as exemplary only, and the true scope and spirit of the present disclosure are set forth by the appended claims.

It should be understood that the present disclosure is not limited to the exact structure that has been described above and illustrated in the drawings, and various modifications and variations can be made without departing from its scope. The scope of the present disclosure is only limited by the appended claims.

1. A method of manufacturing a display substrate, comprising:
providing a substrate;
forming an anode layer on the substrate and a hole injection layer on the anode layer, the anode layer comprising a plurality of anode blocks arranged at intervals, and the hole injection layer comprising a plurality of hole injection portions arranged at intervals, the plurality of hole injection portions disposed on the plurality of anode blocks in a one-to-one correspondence;
forming a pixel definition layer on the hole injection layer, the pixel definition layer provided with a plurality of pixel openings, which expose the plurality of hole injection portions in a one-to-one correspondence;
forming an organic light-emitting material layer which is located at least partially in each of the plurality of pixel openings; and
forming a cathode layer, which covers a side of the organic light-emitting material away from the substrate.

2. The method according to claim 1, wherein material for the hole injection portion comprises a metal oxide;
forming the anode layer on the substrate and the hole injection layer on the anode layer comprises:
forming an anode material film on the substrate and a metal oxide film on the anode material film; and
etching the anode material film and the metal oxide film simultaneously to obtain the plurality of anode blocks and the plurality of hole injection portions.

3. The method according to claim 2, wherein etching the anode material film and the metal oxide film simultaneously comprises:
etching the anode material film and the metal oxide film simultaneously with an etchant which comprises a nitric acid and a phosphoric acid.

4. The method according to claim 2, wherein forming the anode material film on the substrate and the metal oxide film on the anode material film comprises:
forming the anode material film and the metal oxide film on the substrate sequentially through a magnetron sputtering process.

5. The method according to claim 2, wherein material for the hole injection portion comprises at least one of niobium pentoxide, nickel oxide, titanium oxide, and molybdenum oxide.

6. The method according to claim 1, wherein a thickness of the hole injection portion ranges from 10 Å to 30 Å.

7. A display substrate, comprising:
a substrate;
an anode layer, which is disposed on the substrate and comprises a plurality of anode blocks arranged at intervals;
a hole injection layer, which is disposed on the anode layer and comprises a plurality of hole injection portions arranged at intervals, the plurality of hole injection portions disposed on the plurality of anodes in a one-to-one correspondence;
a pixel definition layer, which is provided with a plurality of pixel openings, the plurality of pixel openings exposing the plurality of hole injection portions in a one-to-one correspondence;
an organic light-emitting material layer, disposed at least partially in each of the plurality of pixel openings; and
a cathode layer, disposed on the organic light-emitting layer and covering a side of the organic light-emitting material layer away from the substrate.

8. The display substrate according to claim 7, wherein material for the hole injection portion comprises a metal oxide.

9. The display substrate according to claim 7, wherein material for the hole injection portion comprises at least one of niobium pentoxide, nickel oxide, titanium oxide, and molybdenum oxide.

10. The display substrate according to claim 7, wherein a thickness of the hole injection portion ranges from 10 Å to 30 Å.

11. The display substrate according to claim 7, further comprising a driving circuit layer disposed between the substrate and the anode layer.

12. The display substrate according to claim 7, further comprising a barrier layer and a buffer layer, wherein the barrier layer is disposed between the substrate and the buffer layer, the buffer layer is disposed between the barrier layer and the driving circuit layer.

13. The display substrate according to claim 7, further comprising a hole transport layer and an electron transport layer, wherein the hole transport layer is disposed between the hole injection layer and the organic light-emitting material layer, and the electron transport layer is disposed between the organic light-emitting material layer and the cathode layer.

14. The display substrate according to claim 13, wherein both the hole transport layer and the electron transport layer are a common layer.

15. The display substrate according to claim 7, further comprising a light coupling layer and an encapsulation layer, wherein the light coupling layer is disposed on the cathode layer, and the encapsulation layer is disposed on the light coupling layer.

16. The display substrate according to claim 15, wherein the encapsulation layer is a thin film encapsulation layer.

17. A display panel, comprising the display substrate according to claim 7.

18. The display panel according to claim 17, further comprising a polarizer covering a side of the display substrate facing away from the substrate.

19. A display device, comprising the display panel according to claim 17.
